(19) United States
(12) Patent Application Publication
(10) Pub. No.: US 2022/0278645 A1
(43) Pub. Date: Sep. 1, 2022

(54) PHOTOVOLTAIC COMPONENT

(71) Applicants: Beijing BOE Technology Development Co., Ltd., Beijing (CN); BOE Technology Group Co., Ltd., Beijing (CN)

(72) Inventor: Yuju CHEN, Beijing (CN)

(21) Appl. No.: 17/507,568

(22) Filed: Oct. 21, 2021

(30) Foreign Application Priority Data
Feb. 26, 2021 (CN) 202120426331.7

(51) Int. Cl. H02S 40/10; B08B 7/02; H02S 40/20; H02N 2/00

(52) U.S. Cl. CPC H02S 40/10; B08B 7/02; H02S 40/20; H02N 2/001; H02N 2/0055

(57) ABSTRACT

The embodiment of the disclosure provides a photovoltaic component. A light transmission module of the photovoltaic component covers an upper surface of a solar panel module, and a circuit board module is disposed on a lower surface of the solar panel module, wherein the upper surface and the lower surface are two opposite surfaces of the solar panel module. The light transmission module comprises a transparent substrate and a piezoelectric film layer, wherein the transparent substrate is disposed oblique to the ground, and the piezoelectric film layer is attached to a backlight surface of the transparent substrate. The circuit board module is electrically connected with the piezoelectric film layer, and when the piezoelectric film layer is electrified, the piezoelectric film layer vibrates at different frequencies.

### CROSS REFERENCE TO RELEVANT APPLICATIONS

The present application claims the priority of the Chinese patent application filed on Feb. 26, 2021 before the Chinese Patent Office with the application number of 202120426331.7 and the title of “PHOTOVOLTAIC COMPONENT”, which is incorporated herein in its entirety by reference.

### TECHNICAL FIELD

The disclosure relates to the technical field of display panel manufacturing, in particular to a photovoltaic component.

### BACKGROUND

With the continuous development of photovoltaic technology, photovoltaic products that make life easier have attracted more and more attention from developers. In the technical field of display panel manufacturing, self-cleaning glass receives wide attention because of its self-cleaning property. Self-cleaning glass refers to a type of glass obtained after ordinary glass is subjected to special physical or chemical treatment, so that a surface of the glass has unique physical characteristics, allowing the glass to be cleaned without using traditional manual scrubbing methods.

At present, self-cleaning glass is generally formed by conducting film coating or spray coating on a surface so as to change the properties of the glass surface. Self-cleaning glass may be hydrophobic or hydrophilic to a certain extent. The glass surface needs to be kept clean, allowing water drops to be formed thereon to fall down, so that dirt cannot adhere to the surface easily, thus achieving the effect of self-cleaning.

### SUMMARY

The embodiment of the disclosure provides a photovoltaic component.

The embodiment of the disclosure discloses a photovoltaic component, comprising a light transmission module, a solar panel module and a circuit board module;

Wherein the light transmission module covers an upper surface of the solar panel module, the circuit board module is arranged on a lower surface of the solar panel module, and the upper surface and the lower surface are two opposite surfaces of the solar panel module;

The light transmission module comprises a transparent substrate and a piezoelectric film layer, the transparent substrate is arranged oblique to the ground, and the piezoelectric film layer is attached to a backlight surface of the transparent substrate;

The circuit board module is electrically connected with the piezoelectric film layer, and when the piezoelectric film layer is electrified, the piezoelectric film layer vibrates at different frequencies.

Optionally, the photovoltaic component further comprises a buffer module and an outer frame;

the light transmission module, the solar panel module and the circuit board module are all disposed in a accommodation cavity formed by the outer frame; and

a first gap exists between the light transmission module and the outer frame, a second gap exists between the light transmission module and the solar panel module, and the buffer module is disposed between the first gap and the second gap.

Optionally, the buffer module comprises first foam and second foam;

the first foam is disposed in the first gap, and the second foam is disposed in the second gap.

Optionally, the second foam comprises a plurality of foam strips; and

gaps are provided between the foam strips and the first foam for each two adjacent second foams.

Optionally, the piezoelectric film layer comprises a plurality of piezoelectric ceramic chip sets, each piezoelectric ceramic chip set comprises a plurality of piezoelectric ceramic chips, and the plurality of piezoelectric ceramic chip sets generate two or more mode shapes after being energized.

Optionally, each piezoelectric ceramic chip set extends in a length direction of the transparent substrate, and each two adjacent piezoelectric ceramic chip sets are disposed in parallel, and are spaced from each other.

Optionally, the piezoelectric ceramic chip sets are disposed at equal intervals.

Optionally, each piezoelectric ceramic chip comprises a first electrode, a second electrode, a piezoelectric ceramic wafer, and an encapsulation layer; and

the piezoelectric ceramic wafer is disposed between the first electrode and the second electrode, the second electrode is disposed on the backlight surface of the transparent substrate, and the first electrode, the second electrode and the piezoelectric ceramic wafer are encapsulated by the encapsulation layer.

Optionally, an opening of the encapsulation layer is connected with a first end of a wire, and a second end of the wire is electrically connected with the circuit board module.

Optionally, the circuit board module comprises a driver and a circuit board;

the driver is electrically connected with the circuit board, and the circuit board is electrically connected with the piezoelectric film layer; and

the driver has a plurality of driving modes, the piezoelectric film layer has a plurality of mode shapes, one of the driving modes corresponds to one of the mode shapes, and the plurality of driving modes are cyclically switched.

Optionally, the light transmission module further comprises a self-cleaning coating, and the self-cleaning coating covers the light receiving surface of the transparent substrate.

Optionally, an included angle between a plane where the transparent substrate is located and the ground is an acute angle.

### BRIEF DESCRIPTION OF THE DRAWINGS

To describe the technical solutions of the present disclosure more clearly, the accompanying drawings required for describing some embodiments of the present disclosure may be briefly introduced below. Apparently, the accompanying drawings in the following description are merely accompanying drawings of some embodiments of the present disclosure. To those of ordinary skills in the art, other accompanying drawings may also be derived from these accompanying drawings without creative efforts. In addition, the accompanying drawings in the following description may be regarded as schematic diagrams, and are not a limitation on the actual size of the product and the actual process of the method involved in the embodiment of the present disclosure.

FIG. 1 is a structural diagram of a photovoltaic component provided by the disclosure;

FIG. 2 is a diagram of an installation angle of a photovoltaic component provided by the disclosure;

FIG. 3 is a diagram of distribution positions of piezoelectric ceramic chip sets provided by the disclosure; and

FIG. 4 is a structural diagram of a piezoelectric ceramic chip provided by the disclosure.

### DETAILED DESCRIPTION

In order to make the above objects, features and advantages of the disclosure better understood, the disclosure will be described in further detail below with reference to the accompanying drawings and detailed description.

A photovoltaic component provided by the embodiment of the disclosure will be described in detail through specific embodiments and application scenarios with reference to the attached drawings. The traditional self-cleaning glass changes the properties of the glass surface by surface coating or spraying layers, which is so called passive self-cleaning glass, however the film has a short service life and is easily decomposed by sunlight and ultraviolet light. Certainly, this kind of self-cleaning glass has some effects in the short term. However, after a few months at most, there is no difference from ordinary glass. Moreover, the premise of the principle of hydrophobicity or hydrophilicity is that the surface of the glass is required to be very clean, so that the water droplets or water film may slide down. In fact, when the glass is dirty, many complex dirty such as ash layer and oil droplets are attached to the glass, at this time, the water droplets or water film may not slide down. Moreover, the biggest pollution source of building glass surface is dust pollution, so the priority thing to prevent building glass pollution is to prevent dust adhesion. How to overcome the organic salts formed by the deposition of a large amount of dust and rainwater, and not only the passive self-cleaning of surface treatment, but also the active self-cleaning through the driving method is the technical point of this disclosure.

FIG. 1 is a structural diagram of a photovoltaic component provided by the disclosure. As shown in FIG. 1, the photovoltaic component comprises a light transmission module 1, a solar panel module 2 and a circuit board module 3; wherein the light transmission module 1 covers an upper surface of the solar panel module 2, the circuit board module 3 is disposed on a lower surface of the solar panel module 2, and the upper surface and the lower surface are two opposite surfaces of the solar panel module 2; the light transmission module 1 comprises a transparent substrate 11 and a piezoelectric film layer 12, the transparent substrate 11 is disposed oblique to the ground, and the piezoelectric film layer 12 is attached to a backlight surface of the transparent substrate 11; and the circuit board module 3 is electrically connected with the piezoelectric film layer 12, and when the piezoelectric film layer 12 is electrified, the piezoelectric film layer 12 vibrates at different frequencies.

Specifically, the solar panel module 2 may comprise a solar panel, which is an optoelectronic semiconductor sheet which directly generates electricity by means of sunlight. The solar panel module 2 has an upper surface and a lower surface opposite to each other, wherein the upper surface of the solar panel module 2 is a light receiving surface of the solar panel module 2, so the light transmission module 1 may cover the upper surface of the solar panel module 2 by gluing, electroplating, etc. Since the light transmission module 1 allows light to be transmitted, it will not affect the power generation of the solar panel module 2. The circuit board module 3 may be disposed on the lower surface of the solar panel module 2, and the circuit board may be a flexible circuit board. During installation, the circuit board module 3 and the solar panel module 2 may be encapsulated together in a solar panel encapsulation layer 12114 to protect the circuit board module 3 against damage.

The light transmission module 1 may comprise a transparent substrate 11 and a piezoelectric film layer 12. The transparent substrate 11 may be any material allowing light to be transmitted, such as a glass substrate, an acrylic substrate, a solar panel substrate and a waved board substrate. Take the glass substrate as an example. Besides acid and alkali resistance and corrosion resistance, the glass substrate should have good light transmittance to ensure that all the light passes without reflection or refraction. The transparent substrate 11 has two opposite surfaces, namely a light receiving surface and a backlight surface, wherein the light receiving surface is a surface, away from the solar panel module 2 of the transparent substrate 11, and the backlight surface is a surface close to the solar panel module 2. The piezoelectric film layer 12 is a film layer which may vibrate locally after being electrified. In the embodiment of the disclosure, the piezoelectric film layer 12 may comprise a plurality of piezoelectric film layer 12 sheets or a plurality of piezoelectric film layer chips, which is not limited in the embodiment of the disclosure.

It should be noted that organic salinization particles formed when dust and rainwater are deposited on a film or sprayed coating may be removed by the electric film layer attached to the backlight surface of the light transmission module 1. Specifically, the circuit board module 3 is electrically connected with the piezoelectric film layer 12, and when the piezoelectric film layer 12 is electrified, the piezoelectric film layer 12 vibrates at different frequencies. It should also be noted that, in order to separate the organic salinization particles formed by dust and rainwater deposition from the light receiving surface of the transparent substrate 11 under their own gravity during vibration, the transparent substrate 11 should be oblique with respect to the ground so that a slope exists between a plane where the transparent substrate 11 is located and the ground.

It may be seen from the above embodiment that, in the embodiment of the disclosure, the light transmission module 1 comprises the transparent substrate 11 and the piezoelectric film layer 12, the piezoelectric film layer 12 is attached to the backlight surface of the transparent substrate 11, the circuit board module 3 is electrically connected with the piezoelectric film layer 12, and when the piezoelectric film layer 12 is electrified, the piezoelectric film layer 12 vibrates at different frequencies; therefore, organic salinization particles generated by dust and rainwater deposition will be separated from the light receiving surface of the transparent substrate 11 under the vibration of the piezoelectric film layer 12; in addition, because the transparent substrate 11 is oblique with respect to the ground, the particles may be removed from the light receiving surface of the transparent substrate 11 under their own gravity, so that the cleanliness of the surface of the transparent substrate 11 may be maintained, and the light transmittance of the light transmission module 1 will not be affected.

Optionally, the photovoltaic component further comprises a buffer module 4 and an outer frame 5. The light transmission module 1, the solar panel module and the circuit board module 3 are all disposed in a accommodation cavity formed by the outer frame 5. A first gap exists between the light transmission module 1 and the outer frame 5, a second gap exists between the light transmission module 1 and the solar panel module 2, and the buffer module 4 is disposed in the first gap and the second gap.

Specifically, in the embodiment of the disclosure, the outer frame 5 is a frame for protecting the photovoltaic component, which may be made of a metal frame. Preferably, the outer frame 5 is an aluminum frame. Since the density of aluminum is 2.7*10³ kg/m³, and the relative weight is quite light, the weight of the photovoltaic component may be minimized while sufficient strength of the outer frame 5 is ensured. In addition, because the metal activity of aluminum is quite low, by arranging the aluminum outer frame 5 outside the light transmission module 1, the solar panel module and the circuit board module 3, corrosion on a surface of the photovoltaic component may be avoided to a certain extent, thereby prolonging the service life of the photovoltaic component. It should be noted that since the first gap exists between the light transmission module 1 and the outer frame 5 and the second gap exists between the light transmission module 1 and the solar panel module 2, when the buffer module 4 is disposed in the first gap and the second gap, a buffer effect is generated between the solar panel module 2, the outer frame 5 and the light transmission module 1, thereby reducing the damage when the solar panel module 2, the outer frame 5 and the light transmission module 1 collide. It should also be noted that the buffer module may be any elastic material such as foam and sponge, whose specific shape is determined according to the shapes of the first gap and the second gap, which is not limited by the embodiment of the disclosure.

Optionally, the buffer module comprises first foams 41 and second foams 42, the first foams 41 are disposed in the first gap, and the second foams 42 are disposed in the second gap.

Specifically, the first foams 41 and the second foams 42 are both high-density foams, the first foams 41 are disposed in the first gap to serve as a buffer between the outer frame 5 and the light transmission module 1, and the second foams 42 are disposed in the second gap to serve as a buffer between the solar panel module 2 and the light transmission module 1. It should be noted that in the embodiment of the disclosure, the first gap exists between two sides of the transparent substrate 11 and the outer frame 5, and the second gap exists between the backlight surface of the transparent substrate 11 and the upper surface of the solar panel module 2.

Optionally, the second foam 42 comprises a plurality of foam strips 422, and gaps exist between the foam strips 422 and the first foams 41 and between every two adjacent second foams 42.

It should be noted that the gaps existing between the foam strips 422 and the first foams 41 and between every two adjacent second foams 42 may be equal or different, which is not limited by the embodiment of the disclosure. Since the gaps exist between the foam strips 422 and the first foams 41 and between every two adjacent second foams 42, an air gap exists between the backlight surface of the transparent substrate 11 and the upper surface of the solar panel module 2, which may provide a space required by the vibration of the piezoelectric film layer 12, thereby preventing the transparent substrate 11 from colliding with the solar panel module 2 during vibration.

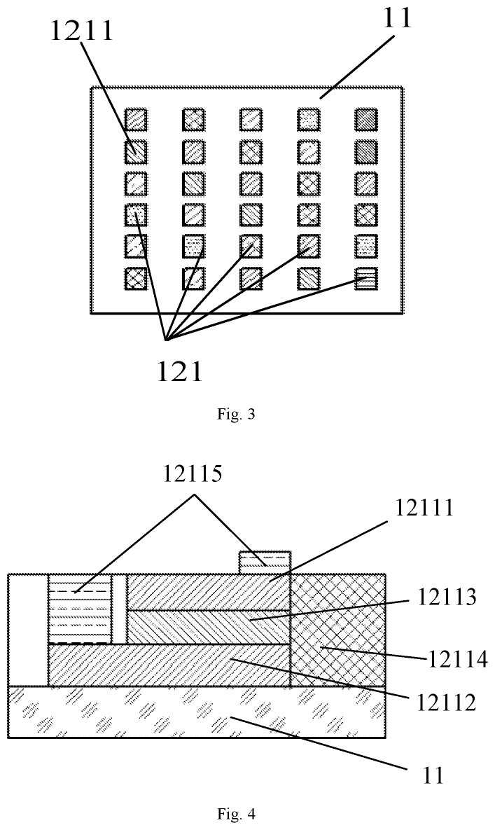

Optionally, as shown in FIG. 3, the piezoelectric film layer 12 comprises a plurality of piezoelectric ceramic chip sets 121, each piezoelectric ceramic chip set 121 comprises a plurality of piezoelectric ceramic chips 1211, and the plurality of piezoelectric ceramic chip sets 121 generate two or more mode shapes after being energized.

It should be noted that each piezoelectric ceramic chip set 121 comprises a plurality of piezoelectric ceramic chips 1211, and the piezoelectric ceramic chips 1211 included in each piezoelectric ceramic chip set 121 have two or more types of piezoelectric film patterns, so that two or more mode shapes are generated after the plurality of piezoelectric ceramic chip sets are energized. In this way, the organic salinization particles formed by dust and rainwater deposition may be quickly separated from the light receiving surface of the transparent substrate 11 under the action of different mode shapes, like each piezoelectric ceramic chip set 121 may comprise five piezoelectric ceramic chips 1211, and the piezoelectric film layer 12 comprises five piezoelectric ceramic chip sets 121, or each piezoelectric ceramic chip set 121 may comprise six piezoelectric ceramic chips 1211, and the piezoelectric film layer 12 comprises seven piezoelectric ceramic chip sets 121. The number of the piezoelectric ceramic chip sets 121 and the number of the piezoelectric ceramic chips 1211 in this embodiment of the disclosure are not limited. It should also be noted that each piezoelectric ceramic chip 1211 may be a square chip, and a side length of each piezoelectric ceramic chip 1211 is greater than 10 μm and a thickness is greater than 1 μm, thus ensuring that the piezoelectric ceramic chip 1211 may vibrate at a certain frequency.

Optionally, each piezoelectric ceramic chip set 121 extends in a length direction of the transparent substrate 11, and every two adjacent piezoelectric ceramic chip sets 121 are disposed in parallel, and are spaced from each other.

Specifically, when every two adjacent piezoelectric ceramic chip sets 121 are disposed in parallel, different mode shapes may be generated between the piezoelectric ceramic chip sets 121. At a specific resonance frequency, the organic salinization particles formed by dust and rainwater deposition may be disposed regularly, which is beneficial to the separation of the particles from the light receiving surface of the light transmission module 1. In addition, because every two adjacent piezoelectric ceramic chip sets 121 are spaced from each other, a surface of the piezoelectric film layer 12 is not completely covered, so that when the piezoelectric film layer 12 is disposed on the backlight surface of the transparent substrate 11, the piezoelectric film layer 12 may still have a high light transmittance, which usually needs to reach 80%, thereby reducing the influence on the power generation of the solar panel module 2 connected with the backlight surface of the light transmission module 1.

Optionally, the piezoelectric ceramic chip sets 121 are disposed at equal intervals.

It should be noted that when the piezoelectric ceramic chip sets 121 are disposed at equal intervals, the light transmittance of all parts of the transparent substrate 11 may be kept consistent, thereby ensuring the light transmittance of the whole transparent substrate 11.

Optionally, as shown in FIG. 4, each piezoelectric ceramic chip 1211 comprises a first electrode 12111, a second electrode 12112, a piezoelectric ceramic wafer 12113 and an encapsulation layer 12114, the piezoelectric ceramic wafer 12113 is disposed between the first electrode 12111 and the second electrode 12112, the second electrode 12112 is disposed on the backlight surface of the transparent substrate 11, and the first electrode 12111, the second electrode 12112 and the piezoelectric ceramic wafer 12113 are encapsulated by the encapsulation layer 12114.

It should be noted that both the first electrode 12111 and the second electrode 12112 may be conductive glass, which allows the first electrode 12111 and the second electrode 12112 to have a high light transmittance while ensuring the conductivity, thereby reducing the influence of the piezoelectric film layer on the power generation of the solar panel module 2. In addition, a thickness of the first electrode 12111 and a thickness of the second electrode 12112 are both greater than 100 nm. The piezoelectric ceramic wafer 12113 is encapsulated between the first electrode 12111 and the second electrode 12112 through the encapsulation layer 12114, so that the first electrode 12111, the second electrode 12112 and the piezoelectric ceramic wafer 12113 are integrated. An encapsulation material may be silicone, epoxy resin, acrylic resin, silicon dioxide, silicon nitride, silica gel and other sealing materials, which may avoid the damage to the piezoelectric ceramic wafer 12113. In this way, the piezoelectric ceramic wafer 12113 may be energized through the first electrode 12111 and the second electrode 12112, and then the piezoelectric ceramic wafer 12113 vibrates with different mode shapes.

Optionally, an opening of the encapsulation layer 12114 is connected with a first end of a wire 12115, and a second end of the wire 12115 is electrically connected with the circuit board module 3.

It should be noted that after the opening of the encapsulation layer 12114 is connected with the first end of the wire 12115, and the second end of the wire 12115 is electrically connected with the circuit board module 3, the first electrode 12111 and an energized state of the first electrode 12111 may be controlled by the circuit board module 3, so as to change the vibration shape of the piezoelectric ceramic wafer 12113, making the whole process controllable.

Optionally, the circuit board module 3 comprises a driver and a circuit board, the driver is electrically connected with the circuit board, and the circuit board is electrically connected with the piezoelectric film layer 12. The driver has a plurality of driving modes, the piezoelectric film layer 12 has a plurality of mode shapes, one of the driving modes corresponds to one of the mode shapes, and the plurality of driving modes are cyclically switched.

It should be noted that since the driver has a plurality of driving modes, in each driving mode, the piezoelectric film layer 12 may vibrate with a vibration shape corresponding to the driving mode, so that the light receiving surface of the transparent substrate 11 may vibrate with different resonance frequencies. Specifically, if the driver has four driving modes corresponding to four mode shapes, after the driver drives the piezoelectric film layer 12 to vibrate in the first vibration mode, the second vibration mode, the third vibration mode and the fourth vibration mode in turn, the piezoelectric film layer 12 is driven to rotate in the first vibration mode to the fourth vibration mode in turn again, so that different resonance frequencies may be generated, allowing particles of different sizes on the light receiving surface of the transparent substrate 11 to be disposed at specific resonance frequencies; in this way, all areas of the light receiving surface of the transparent substrate 11 experience vibration, thereby avoiding residual pollutants at specific positions and further improving the cleanliness of the light receiving surface of the light transmission module 1.

Optionally, the light transmission module 1 further comprises a self-cleaning coating 13, and the self-cleaning coating covers the light receiving surface of the transparent substrate.

It should be noted that since the light receiving surface of the light transmission module 1 is a surface where the light transmission module 1 makes contact with the environment, the self-cleaning coating 13 may cover the light receiving surface of the transparent substrate 11 to further improve the cleaning effect of the light receiving surface of the transparent substrate 11. Specifically, the self-cleaning coating 13 may cover the light receiving surface of the transparent substrate 11 by gluing, electroplating, etc., so that pollutants such as particles in the environment may be removed under the action of the self-cleaning coating 13 to further ensure the cleanliness of the light receiving surface of the self-cleaning glass. It should also be noted that the self-cleaning coating 13 may be any one of silicone coating, titanium dioxide coating or inorganic nano-silicon material coating, which is not limited by the embodiment of the disclosure. Take the titanium dioxide coating as an example. The titanium dioxide coating may be made into a titanium dioxide photocatalyst film, and when the coating is irradiated by sunlight, fluorescent lamps, ultraviolet rays, etc., organic substances and pollutants attached to the surface will be changed into carbon dioxide and water and automatically eliminated under the excitation of light, so as to achieve the cleaning effect.

Optionally, an included angle between a plane where the transparent substrate 11 is located and the ground is an acute angle.

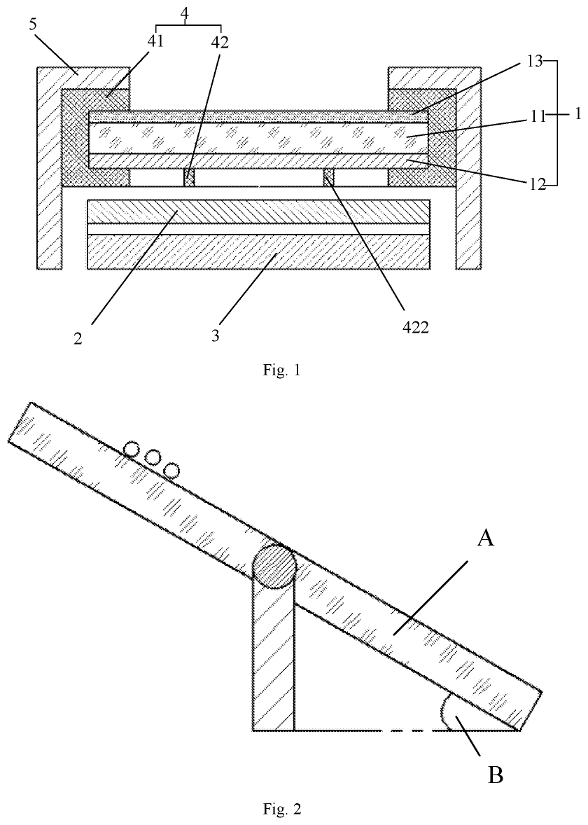

Specifically, an included angle between a light receiving surface of the plane where the transparent substrate 11 is located and the ground is greater than an acute angle shown in FIG. 2, for example, 30°, 45° and 60°, which is not limited by the embodiment of the disclosure, where A is a photovoltaic component and B is the included angle between the light receiving surface of the transparent substrate 11 and the ground. In this way, the particles may be removed from the light receiving surface of the transparent substrate 11 under their own gravity during vibration.

It may be seen from the above embodiment that, in the embodiment of the disclosure, the light transmission module 1 comprises the transparent substrate 11 and the piezoelectric film layer 12, the self-cleaning coating 13 is attached to the light receiving surface of the transparent substrate 11, the piezoelectric film layer 12 is attached to the backlight surface of the transparent substrate 11, the circuit board module 3 is electrically connected with the piezoelectric film layer 12, and when the piezoelectric film layer 12 is electrified, the piezoelectric film layer 12 vibrates at different frequencies; therefore, organic salinization particles generated by dust and rainwater deposition will be separated from the light receiving surface of the transparent substrate 11 under the vibration of the piezoelectric film layer 12; in addition, because the transparent substrate 11 is oblique with respect to the ground, the particles may be removed from the light receiving surface of the transparent substrate 11 under their own gravity, so that the cleanliness of the surface of the transparent substrate 11 may be maintained, and the light transmittance of the light transmission module 1 will not be affected.

All the embodiments in this specification are described in a progressive way, and each embodiment focuses on the differences from other embodiments. The same and similar parts among the embodiments are referable to one another.

Although the preferred embodiments of the disclosure have been described, those skilled in the art can make additional changes and modifications to these embodiments once they know the basic inventive concepts. Therefore, the appended claims are intended to be interpreted as including the preferred embodiments and all changes and modifications that fall within the scope of the disclosure.

It should be also noted that herein, relational terms such as “first” and “second” are only used to distinguish one entity or operation from another entity or operation, and do not necessarily require or imply any such actual relationship or order between these entities or operations. The terms “comprise”, “include” or any other variations thereof, are intended to cover a non-exclusive inclusion, such that a process, method, article, or terminal equipment which includes a list of elements does not include only those elements but also other elements not expressly listed or inherent to such process, method, article, or terminal equipment. Without further limitation, an element defined by the statement “includes a . . . ” does not exclude the presence of another identical element in a process, method, article or terminal equipment that includes the element.

The photovoltaic component provided by the disclosure is described in detail above. Specific examples are applied herein to illustrate the principle and implementation of the disclosure. The above embodiments are only used to help understand the method of the disclosure and its core ideas. For those of ordinary skill in the art, according to the idea of the disclosure, there will be some changes in the specific implementation and application scope. To sum up, the contents of this specification should not be understood as a limitation of the disclosure.

1. A photovoltaic component, comprising a light transmission module, a solar panel module and a circuit board module;
wherein the light transmission module covers on an upper surface of the solar panel module, the circuit board module is disposed on a lower surface of the solar panel module, and the upper surface and the lower surface are two opposite surfaces of the solar panel module;
the light transmission module comprises a transparent substrate and a piezoelectric film layer, the transparent substrate is disposed oblique to the ground, and the piezoelectric film layer is attached to a backlight surface of the transparent substrate; and
the circuit board module is electrically connected with the piezoelectric film layer, and when the piezoelectric film layer is energized, the piezoelectric film layer vibrates at different frequencies.

2. The photovoltaic component according to claim 1, wherein the photovoltaic component further comprises a buffer module and an outer frame;
the light transmission module, the solar panel module and the circuit board module are all disposed in a accommodation cavity formed by the outer frame; and
a first gap exists between the light transmission module and the outer frame, a second gap exists between the light transmission module and the solar panel module, and the buffer module is disposed between the first gap and the second gap.

3. The photovoltaic component according to claim 2, wherein the buffer module comprises first foam and second foam;
the first foam is disposed in the first gap, and the second foam is disposed in the second gap.

4. The photovoltaic component according to claim 3, wherein the second foam comprises a plurality of foam strips; and
gaps are provided between the foam strips and the first foam for each two adjacent second foams.

5. The photovoltaic component according to claim 1, wherein the piezoelectric film layer comprises a plurality of piezoelectric ceramic chip sets, each piezoelectric ceramic chip set comprises a plurality of piezoelectric ceramic chips, and the plurality of piezoelectric ceramic chip sets generate two or more mode shapes after being energized.

6. The photovoltaic component according to claim 5, wherein each piezoelectric ceramic chip set extends in a length direction of the transparent substrate, and each two adjacent piezoelectric ceramic chip sets are disposed in parallel, and are spaced from each other.

7. The photovoltaic component according to claim 6, wherein the piezoelectric ceramic chip sets are disposed at equal intervals.

8. The photovoltaic component according to claim 5, wherein each piezoelectric ceramic chip comprises a first electrode, a second electrode, a piezoelectric ceramic wafer, and an encapsulation layer; and
the piezoelectric ceramic wafer is disposed between the first electrode and the second electrode, the second electrode is disposed on the backlight surface of the transparent substrate, and the first electrode, the second electrode and the piezoelectric ceramic wafer are encapsulated by the encapsulation layer.

9. The photovoltaic component according to claim 8, wherein an opening of the encapsulation layer is connected with a first end of a wire, and a second end of the wire is electrically connected with the circuit board module.

10. The photovoltaic component according to claim 1, wherein the circuit board module comprises a driver and a circuit board;
the driver is electrically connected with the circuit board, and the circuit board is electrically connected with the piezoelectric film layer; and
the driver has a plurality of driving modes, the piezoelectric film layer has a plurality of mode shapes, one of the driving modes corresponds to one of the mode shapes, and the plurality of driving modes are cyclically switched.

11. The photovoltaic component according to claim 1, wherein the light transmission module further comprises a self-cleaning coating, and the self-cleaning coating covers the light receiving surface of the transparent substrate.

12. The photovoltaic component according to claim 1, wherein an included angle between a plane where the transparent substrate is located and the ground is an acute angle.
